(19) United States
(12) Patent Application Publication
(10) Pub. No.: US 2026/0085603 A1
(43) Pub. Date: Mar. 26, 2026

(54) FAULT-AVOIDANCE STREAMLINE CALCULATION METHOD FOR RESERVOIR WELL PATTERN

(71) Applicant: Qingdao University of Science and Technology, Qingdao City (CN)

(72) Inventors: Haoran Cheng, Qingdao City (CN); Yao Meng, Qingdao City (CN); Guang Zhao, Qingdao City (CN); Luyang Sun, Qingdao City (CN); Hongjie Zhao, Qingdao City (CN); Kai Yu, Qingdao City (CN)

(21) Appl. No.: 19/403,118

(22) Filed: Nov. 27, 2025

(30) Foreign Application Priority Data
Dec. 5, 2024 (CN) 202411774700.6

(51) Int. Cl. E21B 47/00; G01V 1/28; G01V 1/30; G06F 30/28

(52) U.S. Cl. CPC E21B 47/00; G01V 1/282; G01V 1/302; G06F 30/28; E21B 2200/20

(57) ABSTRACT

A fault-avoidance streamline calculation method for reservoir well pattern include: establishing a three-dimensional reservoir geological model using seismic and geological exploration data, and obtaining a grid-based reservoir model using triangulation technique; performing streamline simulation, and generating a streamline distribution of a reservoir well pattern in the grid-based reservoir model; determining a risk of contact between a streamline and a fault, and calculating an avoidance path; optimizing and adjusting well locations to ensure that the streamline and the fault do not intersect; and performing streamline verification. The method realizes efficient development of reservoirs.

### TECHNICAL FIELD

The disclosure relates to the field of streamline calculation in reservoir development, and in particular to a fault-avoidance streamline calculation method for reservoir well pattern.

### BACKGROUND

Reasonable well pattern layout in reservoir development is a key factor in improving recovery efficiency and optimizing resource allocation. However, geological conditions with complex faults bring great challenges to well pattern design, mainly manifested in easy crossing of fault areas by well streamlines, which results in a decrease in fluid recovery efficiency, and may even lead to problems such as oil and gas leakage or well interference. Traditional well pattern design mostly depends on experience or regular layout, lacks systematic fault avoidance calculation method, and cannot fully consider the spatial influence of faults. Based on this, it is crucial to develop an efficient and accurate fault avoidance calculation method to realize reasonable well layout and fault avoidance in reservoir well pattern design.

### SUMMARY

In view of the above technical problems, the present invention provides a fault-avoidance streamline calculation method for reservoir well pattern. By simulating and optimizing streamlines in reservoirs and avoiding fault areas in the well pattern layout, efficient development of the reservoirs can be achieved.

The present invention is realized by the following technical solution.

A fault-avoidance streamline calculation method for reservoir well pattern includes the following steps: (1) establishing a three-dimensional reservoir geological model using seismic and geological exploration data, and obtaining a grid-based reservoir model using Delaunay triangulation technique; (2) performing streamline simulation based on a seepage equation of a subsurface fluid, and generating a streamline distribution of a reservoir well pattern in the grid-based reservoir model; (3) determining a risk of contact between a streamline and a fault, and calculating an avoidance path for the streamline; (4) optimizing and adjusting well locations using a simulated annealing algorithm to ensure that the streamline and the fault do not intersect; and (5) performing streamline verification, and outputting streamline results if the verification is successful, or returning to step (4) if the streamline verification fails.

Further, step (1) is specifically as follows: establishing the three-dimensional reservoir geological model for a reservoir area using seismic data and the geological exploration data; and characterizing a fault structure in the three-dimensional reservoir geological model by polygon boundaries; dividing reservoirs in the three-dimensional reservoir geological model into regular grid unit blocks using the Delaunay triangulation technique to obtain the grid-based reservoir model; and marking the location of the fault in the grid-based reservoir model.

Further, in step (2), the streamline simulation is carried out on the basis of the seepage equation of the subsurface fluid driven by inter-well pressure difference, and the streamline distribution of the reservoir well pattern is generated in the grid-based reservoir model, and the specific steps include:
(2.1) establishing a pressure field distribution using a seepage governing equation:

$$∇ \cdot ( k ∇ p ) = q$$

where ∇ is a divergence operator, k is a permeability tensor, p is a pressure, ∇p is a pressure gradient, and q is a source sink term;
according to oil well locations, when q>0, a corresponding well is set as an injection well, when q<0, a corresponding well is set as a production well, and the permeability value is set at the fault;
(2.2) using a velocity field to calculate a flow trajectory X(t) of fluid particles, and calculating the streamline distribution from each well location, and the streamline equation is:

$$\frac{dX ( t )}{dt} = V ( X ( t ) ) ;$$

where V is Darcy velocity,

$$V = - \frac{k}{μ} ∇ p ,$$

k is the permeability tensor, μ is fluid viscosity, and ∇p is the pressure gradient; and
(2.3) in a fault area, adjusting a flow direction of the streamline by locally adjusting the permeability.

Further, step (3) includes the following steps:
(3.1) for the locations of any two wells, obtaining four three-dimensional coordinate points perpendicular to a plane according to an effective perforation depth, and then obtaining a plane equation corresponding to the streamline between the two wells:

$${A}_{1} x + {B}_{1} y + {C}_{1} z + {D}_{1} = 0 ;$$

where \vec{n}₁, is a normal vector \vec{n}₁=(A₁, B₁, C₁) the plane corresponding to the streamline between the two wells, and D₁ is a constant;
x, y and z respectively represent an x axis, a y axis and a z axis in a three-dimensional coordinate system;
(3.2) representing a fault plane using the following plane equation:

$${A}_{2} x + {B}_{2} y + {C}_{2} z + {D}_{2} = 0 ;$$

\vec{n}₂ is a normal vector of a plane corresponding to the fault plane \vec{n}₂=(A₂, B₂, C₂); and D₂ is a constant;
(3.3) by using the intersection point judgment method, first finding an intersection line equation by simultaneously solving the two plane equations, and then determining whether the intersection line intersects sides of two quadrilaterals, and if so, determining that the corresponding streamline is at risk of contact with the fault;
(3.4) for the streamline that is at risk of contact with the fault, adjusting direction of the streamline by the angle deflection method to keep the streamline away from the fault area;
a formula for calculating a deflection angle θ the streamline is:

$$θ = arccos ( \frac{V \cdot n}{\vert V \vert \vert n \vert} ) ;$$

where

$$V = - \frac{k}{μ} ∇ p ,$$

n is a normal vector of the fault; and
(3.5) smoothing the path after adjustment of the streamline using the path smoothing algorithm Bezier curve.

Further, step (4) includes the following steps:
(4.1) defining an objective function F for well location optimization to minimize a contact distance between the well and the fault and maximize recovery efficiency:

$$min F = {\sum }_{i} α {d}_{i} + β {R}_{i} + γ {C}_{i}$$

Where dᵢ is a penalty term for the distance between the well streamline and the fault; Rᵢ is degree of well interference; Cᵢ is a recovery efficiency correlation coefficient; α [symbol] β [symbol] γ is a weight coefficient; and i represents a group of wells or a well;
(4.2) executing the simulated annealing algorithm, setting an initial temperature, randomly disturbing the well locations, accepting an excellent solution, gradually cooling down, and finally obtaining optimal well locations; and
(4.3) making adjustment according to the optimization results; and calculating the streamline distribution of the adjusted well locations to ensure that the streamline and the fault do not intersect.

Further, in step (5), the streamline verification is performed by analyzing the streamline distribution of the well pattern optimized in the step (4) through fluid simulation, and if the streamline and the two three-dimensional planes formed between faults do not intersect, the avoidance is determined to be successful and the verification passes; and if the streamline and the two three-dimensional planes formed between the faults intersect, the avoidance is determined to be unsuccessful, the streamline verification fails, and the process returns to the step (4).

Further, the step (5) further includes updating the three-dimensional reservoir geological model through verification.

The present invention has the following beneficial effects.

The present invention provides a systematic fault avoidance calculation method based on numerical simulation. The method provided by the present invention accurately characterizes the fault structure using polygon boundaries and builds a grid-based reservoir model through Delaunay triangulation technique, which can present various spatial characteristics of faults in detail. Meanwhile, permeability and porosity of the fault area are set differently in the grid-based reservoir model to more realistically simulate the characteristics of faults as fluid barriers or diversion channels, providing a solid foundation for subsequent accurate streamline simulation and fault avoidance calculation.

The method provided by the present invention adopts streamline simulation, takes the flow equation of the fluid driven by inter-well pressure difference as the basis, fully considers the influence of permeability change at the fault on the velocity field in the calculation process, can accurately simulate sudden change in the velocity field occurring in the streamline simulation for the fault area, and reasonably adjust the flow direction of the streamline by locally adjusting the permeability, thus generating a streamline distribution more in line with the actual reservoir conditions.

The present invention accurately calculates the closest contact distance between the streamline and the fault, adopts the intersection point judgment method to determine whether the streamline and the fault intersect, and combines the angle deflection method and the path smoothing algorithm to optimize the streamline path, which effectively avoids the contact between a high-risk streamline and the fault, and improves the rationality and stability of the well pattern layout.

The present invention uses the simulated annealing algorithm to realize path optimization and well location adjustment, and realizes scientific optimization of well locations by defining an objective function that incorporates multiple factors such as contact distance between wells and faults, degree of well interference and recovery efficiency, ensuring that well location distribution meets fault avoidance requirements while maximizing the recovery efficiency, which is difficult to achieve with the prior art.

### BRIEF DESCRIPTION OF THE DRAWINGS

FIG. 1 is an intersection diagram of a streamline and a fault plane according to an embodiment of that present invention; and

FIG. 2 is a flowchart of a fault-avoidance streamline calculation method for reservoir well pattern according to an embodiment of the present invention.

### DESCRIPTION OF THE EMBODIMENTS

To make the purpose, technical solution and advantages of the present invention more clear, the present invention will be further described in detail below in conjunction with the accompanying drawings and embodiments. It should be understood that the specific embodiments described herein are merely illustrative of the present invention and are not intended to limit the present invention.

On the contrary, the present invention covers any alternatives, modifications, equivalents, and solutions as defined by the claims within the spirit and scope of the present invention. Furthermore, in order to provide the public with a better understanding of the present invention, some specific details are described in detail in the following detailed description of the present invention. The present invention will be fully understood by those skilled in the art without the description of these details.

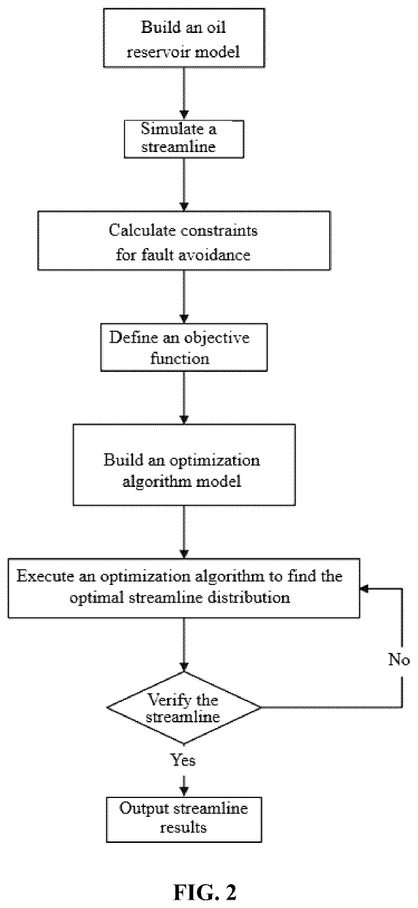

Provided is an embodiment of a fault-avoidance streamline calculation method for reservoir well pattern. As shown in FIG. 2, the method includes the following steps: (1) establishing a three-dimensional reservoir geological model using seismic and geological exploration data, and obtaining a grid-based reservoir model using Delaunay triangulation technique; (2) performing streamline simulation based on a seepage equation of a subsurface fluid, and generating a streamline distribution of a reservoir well pattern in the grid-based reservoir model; (3) determining a risk of contact between a streamline and a fault, and calculating an avoidance path for the streamline; (4) optimizing and adjusting well locations using a simulated annealing algorithm to ensure that the streamline and the fault do not intersect; and (5) performing streamline verification, and outputting streamline results if the verification is successful, or returning to step (4) if the streamline verification fails.

In the present embodiment, step (1) is specifically as follows: establishing the three-dimensional reservoir geological model for a reservoir area using seismic data and the geological exploration data; and characterizing a fault structure in the three-dimensional reservoir geological model by polygon boundaries, where fault parameters include dip angle, strike, location and extension depth of the fault; dividing reservoirs in the three-dimensional reservoir geological model into regular grid unit blocks (e.g., tetrahedral units or hexahedral units) using the Delaunay triangulation technique to obtain the grid-based reservoir model Ω(x, y, z), where the grid unit blocks have uniform physical parameters; and marking the location of the fault in the three-dimensional reservoir geological model to enable identification and avoidance in subsequent streamline calculations.

Here, Delaunay triangulation is a common method for irregular grid division on a two-dimensional plane. It divides a set of points on the plane into a series of triangles, causing the triangular grids to have good geometric properties. The formula is as follows:
for any triangle ΔABC, there is no fourth point D that falls within a circumcircle of ΔABC, that is:

$${( {x}_{A} - {x}_{D} )}^{2} + {( {y}_{A} - {y}_{D} )}^{2} > {{r}_{ABC}}^{2}$$

where r_{ABC} is the radius of the circumcircle of triangle ΔABC.

In step (2) of the present embodiment, the streamline simulation is carried out on the basis of the seepage equation of the subsurface fluid driven by inter-well pressure difference, and the streamline distribution of the reservoir well pattern is generated in the grid-based reservoir model, and the specific steps include:
(2.1) Establishing a pressure field distribution using a seepage governing equation:

$$∇ \cdot ( k ∇ p ) = q$$

where ∇ is a divergence operator, k is a permeability tensor, p is a pressure, ∇p is a pressure gradient, and q is a source sink term;
where ∇ is the divergence operator used to describe the degree of divergence or convergence of a vector field. k is the permeability tensor, and describes the resistance of a medium to fluid flow. The permeability tensor can be anisotropic, that is, having different permeabilities in different directions. ∇p is the pressure gradient, which represents the spatial rate of change of the pressure field. q is the source sink term, which represents the fluid source (positive value) or sink (negative value) per unit volume;
according to oil well locations, when q>0, a corresponding well is set as an injection well, when q<0, a corresponding well is set as a production well, the permeability value is set at the fault, and the permeability value is set to a smaller value (less than 50×10\hat{ }(−3)μm² by default) or zero.
(2.2) Using a velocity field to calculate a flow trajectory X(t) of fluid particles, and calculating the streamline distribution from each well location, and the streamline equation is:

$$\frac{dX ( t )}{dt} = V ( X ( t ) ) ;$$

where V is Darcy velocity,

$$V = - \frac{k}{μ} ∇ p ,$$

k is the permeability tensor, μ is fluid viscosity, and ∇p is the pressure gradient; where V is the Darcy velocity (the average velocity of a fluid in a porous medium); k is the permeability tensor, describes the resistance of the porous medium to fluid flow, and is a second-order tensor that can represent permeability properties of anisotropic media.
(2.3) In a fault area, adjusting a flow direction of the streamline by locally adjusting the permeability. The permeability of some fault areas is set to extremely low values to simulate the characteristics of faults as fluid barriers. In some fault zones, a higher permeability can be set to simulate fault diversion channels. That is, the values of permeability and porosity of the fault areas can be selected and set as needed to realize differentiated settings of permeability and porosity of the fault areas in the grid-based reservoir model being built.

In step (3) of the present embodiment, after the streamline simulation, the risk of contact between the streamline and the fault is determined, and an avoidance path is calculated for the streamline, which includes the following steps:
(3.1) For the locations of any two wells, obtaining four three-dimensional coordinate points perpendicular to a plane according to an effective perforation depth, and then obtaining a plane equation corresponding to the streamline between the two wells:

$${A}_{1} x + {B}_{1} y + {C}_{1} z + {D}_{1} = 0 ;$$

where \vec{n}₁ is a normal vector \vec{n}₁=(A₁, B₁, C₁) of the plane corresponding to the streamline between the two wells, and D₁ is a constant;
x, y and z respectively represent an x axis, a y axis and a z axis in a three-dimensional coordinate system.
(3.2) Representing a fault plane using the following plane equation:

$${A}_{2} x + {B}_{2} y + {C}_{2} z + {D}_{2} = 0 ;$$

\vec{n}₂ is a normal vector of a plane corresponding to the fault plane \vec{n}₂=(A₂, B₂, C₂); and D₂ is a constant.
(3.3) Whether the streamlines and the fault intersect can be expressed as whether two finite planes (quadrilateral planes) intersect in a three-dimensional space; by using the intersection point judgment method in the present invention, first finding an intersection line equation by simultaneously solving the two plane equations, and then determining whether the intersection line intersects sides of two quadrilaterals, and if so, determining that the corresponding streamline is at risk of contact with the fault.

Specifically, the judgment method includes:
finding an intersection equation: setting a direction vector \vec{s} of the intersection line to \vec{s}=\vec{n}₁×x\vec{n}₂, where \vec{n}₁=(A₁, B₁, C₁), \vec{n}₂=(A₂, B₂, C₂).
determining whether the intersection line intersects the sides of the two quadrilaterals: the sides of the two quadrilaterals are line segments, and each line segment is determined separately. For any line segment and the straight line where the intersection line is located, \vec{r}=\vec{r}₀+t\vec{s}, \vec{r}₀ represents a known point on the straight line, which is part of the straight line equation \vec{r}=\vec{r}₀+t\vec{s} and is used to determine the location of the straight line. Here, t is a parameter, and when t takes different values, \vec{r} moves along the straight line \vec{r}₀+t\vec{s}. This equation describes a straight line, where \vec{s} is the direction vector of the straight line.

By substituting end points of the line segments into the values solved by the straight line equation, resulting values are determined to be within the threshold range to determine whether the line segments intersect; if the line segments intersect, the corresponding streamline is determined to be at risk of contact with the fault.

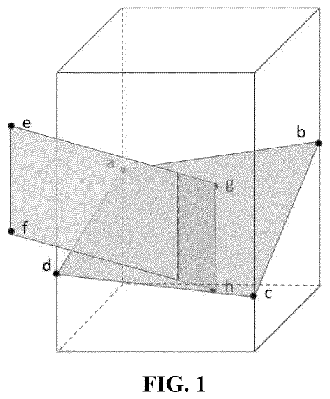

As shown in FIG. 1, a, b, c and d are a plane formed by faults, and e, f, g and h are a plane formed by effective perforation intervals of any two wells, where e and f are from the same well, while g and h are from another well and perpendicular to the ground plane.
(3.4) For the streamline that is at risk of contact with the fault, adjusting direction of the streamline by the angle deflection method to keep the streamline away from the fault area; a formula for calculating a deflection angle θ of the streamline is:

$$θ = arccos ( \frac{V \cdot n}{\vert V \vert \vert n \vert} ) ;$$

Where

$$V = - \frac{k}{μ} ∇ p ,$$

n is a normal vector of the fault.
(3.5) To ensure smoothness of the streamline, smoothing the path after adjustment of the streamline using the path smoothing algorithm Bezier curve. The smoothing algorithm used in this step is a conventional smoothing algorithm.

The step (4) of the present embodiment includes:
(4.1) Defining an objective function/for well location optimization to minimize a contact distance between the well and the fault and maximize recovery efficiency:

$$min F = {\sum }_{i} α {d}_{i} + β {R}_{i} + γ {C}_{i}$$

where dᵢ is a penalty term for the distance between the well streamline and the fault; Rᵢ is degree of well interference; Cᵢ is a recovery efficiency correlation coefficient; α [symbol] β [symbol] γ is a weight coefficient; and i represents a group of wells or a well; iteration is performed for each well; and each well has its own dᵢ, Rᵢ and Cᵢ values.
(4.2) Executing the simulated annealing algorithm, setting an initial temperature, randomly disturbing the well locations, accepting an excellent solution, gradually cooling down, and finally obtaining optimal well locations; where the simulated annealing algorithm used in the present invention is a conventional algorithm.
(4.3) Making adjustments according to the optimization results to ensure that well location distribution meets fault avoidance requirements; and calculating the streamline distribution of the adjusted well locations to ensure that the streamline and the fault do not intersect.

In step (5) of the present embodiment, the streamline verification is performed by analyzing the streamline distribution of the well pattern optimized in the step (4) through fluid simulation, and if the streamline and the two three-dimensional planes formed between faults do not intersect, the avoidance is determined to be successful and the verification passes; and if the streamline and the two three-dimensional planes formed between the faults intersect, the avoidance is determined to be unsuccessful, the streamline verification fails, and the process returns to the step (4).

In the present embodiment, the step (5) further includes updating the three-dimensional reservoir geological model through verification.

The foregoing is merely a preferred embodiment of the present invention, and is not intended to limit the present invention. Any modification, equivalent replacement or improvement made within the spirit and principle of the present invention should be included in the protection scope of the present invention.

What is claimed is:

1. A fault-avoidance streamline calculation method for reservoir well pattern, comprising:
(1) establishing a three-dimensional reservoir geological model using seismic and geological exploration data, and obtaining a grid-based reservoir model using Delaunay triangulation technique;
(2) performing streamline simulation based on a seepage equation of a subsurface fluid, and generating a streamline distribution of a reservoir well pattern in the grid-based reservoir model;
(3) determining a risk of contact between a streamline and a fault, and calculating an avoidance path for the streamline;
(4) optimizing and adjusting well locations using a simulated annealing algorithm to ensure that the streamline and the fault do not intersect; and
(5) performing streamline verification, and outputting streamline results if the verification is successful, or returning to step (4) if the streamline verification fails;
wherein in step (2), the streamline simulation is carried out on the basis of the seepage equation of the subsurface fluid driven by inter-well pressure difference, and the streamline distribution of the reservoir well pattern is generated in the grid-based reservoir model, and the specific steps comprise:
(2.1) establishing a pressure field distribution using a seepage governing equation:
$$∇ \cdot ( k ∇ p ) = q$$
where ∇ is a divergence operator, k is a permeability tensor, p is a pressure, ∇p is a pressure gradient, and q is a source sink term;
according to oil well locations, when q>0, a corresponding well is set as an injection well, when q<0, a corresponding well is set as a production well, and the permeability value is set at the fault;
(2.2) using a velocity field to calculate a flow trajectory X(t) of fluid particles, and calculating the streamline distribution from each well location, and the streamline equation is:
$$\frac{dX ( t )}{dt} = V ( X ( t ) ) ;$$
where ∇ is Darcy velocity,
$$V = - \frac{k}{μ} ∇ p ,$$
k is the permeability tensor, μ is fluid viscosity, and ∇p is the pressure gradient; and
(2.3) in a fault area, adjusting a flow direction of the streamline by locally adjusting the permeability;
step (3) comprises the following steps:
(3.1) for the locations of any two wells, obtaining four three-dimensional coordinate points perpendicular to a plane according to an effective perforation depth, and then obtaining a plane equation corresponding to the streamline between the two wells:
$${A}_{1} x + {B}_{1} y + {C}_{1} z + {D}_{1} = 0 ;$$
where \vec{n}₁ is a normal vector \vec{n}₁=(A₁, B₁, C₁) of the plane corresponding to the streamline between the two wells, and D₁ is a constant;
x, y and z respectively represent an x axis, a y axis and a z axis in a three-dimensional coordinate system;
(3.2) representing a fault plane using the following plane equation:
$${A}_{2} x + {B}_{2} y + {C}_{2} z + {D}_{2} = 0 ;$$
\vec{n}₂ is a normal vector of a plane corresponding to the fault plane \vec{n}₂=(A₂, B₂, C₂), and D₂ is a constant;
(3.3) by using the intersection point judgment method, first finding an intersection line equation by simultaneously solving the two plane equations, and then determining whether the intersection line intersects sides of two quadrilaterals, and if so, determining that the corresponding streamline is at risk of contact with the fault;
(3.4) for the streamline that is at risk of contact with the fault, adjusting direction of the streamline by the angle deflection method to keep the streamline away from the fault area;
a formula for calculating a deflection angle θ of the streamline is:
$$θ = arccos ( \frac{V \cdot n}{\vert V \vert \vert n \vert} ) ;$$
Where
$$V = - \frac{k}{μ} ∇ p ,$$
n is a normal vector of the fault; and
(3.5) smoothing the path after adjustment of the streamline using the path smoothing algorithm Bezier curve;
the step (4) comprises:
(4.1) defining an objective function F for well location optimization to minimize a contact distance between the well and the fault and maximize recovery efficiency:
$$min F = {\sum }_{i} α {d}_{i} + β {R}_{i} + γ {C}_{i}$$
where dᵢ is a penalty term for the distance between the well streamline and the fault; Rᵢ is degree of well interference; Cᵢ is a recovery efficiency correlation coefficient; α [symbol] β [symbol] γ is a weight coefficient; and i represents a group of wells or a well;
(4.2) executing the simulated annealing algorithm, setting an initial temperature, randomly disturbing the well locations, accepting an excellent solution, gradually cooling down, and finally obtaining optimal well locations; and
(4.3) making adjustment according to the optimization results; and calculating the streamline distribution of the adjusted well locations to ensure that the streamline and the fault do not intersect;
in step (5), the streamline verification is performed by analyzing the streamline distribution of the well pattern optimized in the step (4) through fluid simulation, and if the streamline and the two three-dimensional planes formed between faults do not intersect, the avoidance is determined to be successful and the verification passes; and if the streamline and the two three-dimensional planes formed between the faults intersect, the avoidance is determined to be unsuccessful, the streamline verification fails, and the process returns to the step (4).

2. The fault-avoidance streamline calculation method for reservoir well pattern accord to claim 1, wherein the step (1) is specifically as follows:
establishing the three-dimensional reservoir geological model for a reservoir area using seismic data and the geological exploration data; and characterizing a fault structure in the three-dimensional reservoir geological model by polygon boundaries;
dividing reservoirs in the three-dimensional reservoir geological model into regular grid unit blocks using the Delaunay triangulation technique to obtain the grid-based reservoir model; and
marking the location of the fault in the grid-based reservoir model.

3. The fault-avoidance streamline calculation method for reservoir well pattern accord to claim 1, wherein the step (5) further comprises updating the three-dimensional reservoir geological model through verification.
